(19) United States
(12) Patent Application Publication
(10) Pub. No.: US 2024/0234538 A9
(43) Pub. Date: Jul. 11, 2024

(54) HIGH ELECTRON MOBILITY TRANSISTOR AND METHOD FOR FABRICATING THE SAME

(71) Applicants: National Yang Ming Chiao Tung University, Hsinchu city (TW); National Chung-Shan Institute of Science and Technology, Taoyuan City (TW)

(72) Inventors: Edward Yi CHANG, Baoshan Township (TW); You-Chen WENG, New Taipei City (TW); Min-Lu Kao, Chiayi City (TW)

(73) Assignees: National Yang Ming Chiao Tung University, Hsinchu City (TW); National Chung-Shan Institute of Science and Technology, Taoyuan City (TW)

(21) Appl. No.: 18/097,074

(22) Filed: Jan. 13, 2023

(30) Foreign Application Priority Data
Oct. 20, 2022 (TW) 111139821

(51) Int. Cl. H01L 29/66; H01L 29/20; H01L 29/778

(52) U.S. Cl. CPC H01L 29/66462; H01L 29/2003; H01L 29/7786

(57) ABSTRACT

A high electron mobility transistor and a method for fabricating the same is disclosed. Firstly, a lattice matching layer, a channel layer, and an AlGaN layer are sequentially formed on a growth substrate. The AlGaN layer includes a first area, a second area, and a third area, wherein the second area is located between the first area and the third area. Then, an insulation block is formed on the second area of the AlGaN layer and two GaN blocks are respectively formed on the first area and the third area of the AlGaN layer. Two InAlGaN blocks are respectively formed on the GaN blocks and the insulation block is removed. Finally, a gate is formed to interfere the second area of the AlGaN layer and a source and a drain are respectively formed on the InAlGaN blocks.

This application claims priority of application Ser. No. 11/139,821 filed in Taiwan on 20 Oct. 2022 under 35 U.S.C. § 119; the entire contents of all of which are hereby incorporated by reference.

### BACKGROUND OF THE INVENTION

### Field of the Invention

The present invention relates to a transistor, particularly to a high electron mobility transistor and a method for fabricating the same.

### Description of the Related Art

In recent years, industries such as electric vehicles and 5G communication have developed rapidly. The specifications and demand for electronic components have increased. High-power, low-consumption and high-frequency electronic components have market advantages. Among them, an ideal semiconductor material includes GaN with high breakdown voltage, high electron saturation drift velocity, low resistivity, chemical resistance and good thermal stability. However, the high electron mobility transistor (HEMT) mainly made of GaN is affected by the kink effect. During the operation, a large number of electrons enter the buffer layer from the channel layer to decrease output current and signal amplification, which limits the performance and reliability of high electron mobility GaN transistors.

In order to improve the performance of high electron mobility transistors, InAlN and InAlGaN with high carrier density are used. FIG. 1 is a cross-sectional view of a conventional high electron mobility transistor. Referring to FIG. 1, a high electron mobility transistor 1 includes a substrate 10, an AlN nucleation layer 11, an AlGaN transition layer 12, a GaN channel layer 13, an AlN spacer layer 14, and an InAlGaN barrier layer 15. The AlN nucleation layer 11, the AlGaN transition layer 12, the GaN channel layer 13, the AlN spacer layer 14, and the InAlGaN barrier layer 15 are sequentially formed on the substrate 10. However, the InAlGaN barrier layer 15 is limited by electron scattering. The phase difference caused by different growth temperature of In and AlGaN results in low electron mobility and large gate leakage.

To overcome the abovementioned problems, the present invention provides a high electron mobility transistor and a method for fabricating the same, so as to solve the afore-mentioned problems of the prior art.

### SUMMARY OF THE INVENTION

The present invention provides a high electron mobility transistor and a method for fabricating the same, which improve the electron mobility, current density, and transconductance.

In an embodiment of the present invention, a high electron mobility transistor includes a growth substrate, a lattice matching layer, a channel layer, an AlGaN layer, two GaN blocks, two InAlGaN blocks, a gate, a source and a drain. The lattice matching layer is formed on the growth substrate. The channel layer is formed on the lattice matching layer. The AlGaN layer is formed on the channel layer. The AlGaN layer includes a first area, a second area, and a third area. The second area is located between the first area and the third area. The GaN blocks are respectively formed on the first area and the third area of the AlGaN layer. The InAlGaN blocks are respectively formed on the two GaN blocks. The gate directly interfaces the second area of the AlGaN layer. The source and the drain are respectively formed on the two InAlGaN blocks.

In an embodiment of the present invention, a method for fabricating a high electron mobility transistor includes: sequentially forming a lattice matching layer, a channel layer, and an AlGaN layer on a growth substrate, wherein the AlGaN layer includes a first area, a second area, and a third area, and the second area is located between the first area and the third area; forming an insulation block on the second area of the AlGaN layer; respectively forming two GaN blocks on the first area and the third area of the AlGaN layer; respectively forming two InAlGaN blocks on the two GaN blocks; removing the insulation block; and forming a gate to directly interface the second area of the AlGaN layer and respectively forming a source and a drain on the two InAlGaN blocks.

In an embodiment of the present invention, the step of forming the insulation block on the second area of the AlGaN layer includes: sequentially forming an insulation layer and a photoresist layer on the AlGaN layer; removing the photoresist layer directly above the first area and the third area of the AlGaN layer and leaving the photoresist layer directly above the second area of the AlGaN layer; removing the insulation layer directly above the first area and the third area of the AlGaN layer and leaving the insulation layer directly above the second area of the AlGaN layer; and removing the photoresist layer directly above the second area of the AlGaN layer. The insulation layer made of SiNx or SiOx may be formed using PECVD. The photoresist layer may be formed using a spin coater.

In an embodiment of the present invention, the two GaN blocks and the two InAlGaN blocks are formed using metal-organic chemical vapor deposition (MOCVD), atomic layer deposition (ALD), or plasma enhanced chemical vapor deposition (PECVD).

In an embodiment of the present invention, the growth substrate comprises Si, GaN, SiC, or sapphire.

In an embodiment of the present invention, the lattice matching layer comprises GaN.

In an embodiment of the present invention, the channel layer comprises GaN.

To sum up, the high electron mobility transistor and the method for fabricating the same form the GaN blocks between the AlGaN layer and the InAlGaN block to improve the electron mobility, current density, and transconductance.

Below, the embodiments are described in detail in cooperation with the drawings to make easily understood the technical contents, characteristics and accomplishments of the present invention.

### BRIEF DESCRIPTION OF THE DRAWINGS

FIG. 1 is a cross-sectional view of a conventional high electron mobility transistor;

FIG. 2 is a cross-sectional view of a high electron mobility transistor of the present invention;

FIG. 3 is a diagram illustrating curves of a drain current and a drain-source voltage corresponding to FIG. 1 and FIG. 2;

FIG. 4 is a diagram illustrating curves of a transconductance, a drain current and a gate-source voltage corresponding to FIG. 1 and FIG. 2;

FIG. 5 is a cross-sectional view of a high electron mobility transistor according to an embodiment of the present invention; and

FIGS. 6(a)-6(h) are diagrams schematically illustrating the step of fabricating a high electron mobility transistor according to an embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Certain terms are used throughout the description and the claims to refer to particular components. One skilled in the art appreciates that a component may be referred to using different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

In the following description, a high electron mobility transistor and a method for fabricating the same will be described, which forms GaN blocks between an AlGaN layer and an InAlGaN block to improve the electron mobility, current density, and transconductance.

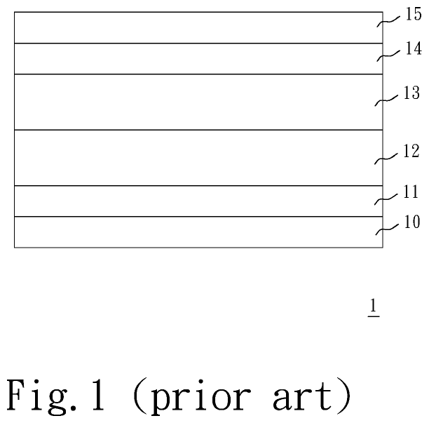

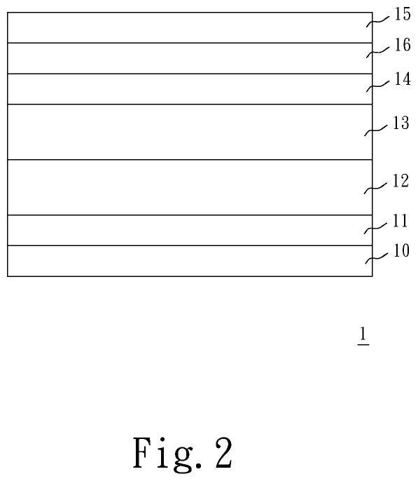

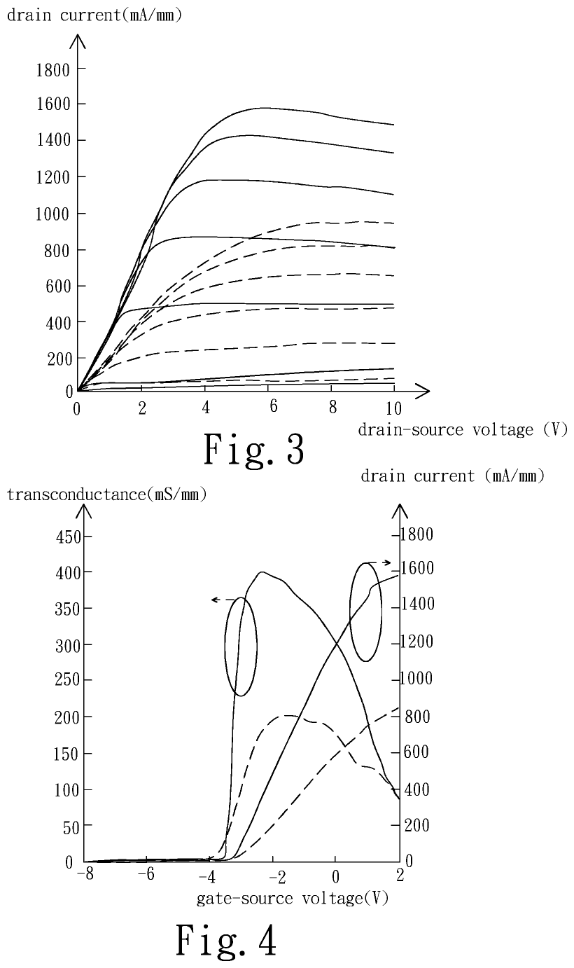

FIG. 2 is a cross-sectional view of a high electron mobility transistor of the present invention. FIG. 3 is a diagram illustrating curves of a drain current and a drain-source voltage corresponding to FIG. 1 and FIG. 2. FIG. 4 is a diagram illustrating curves of a transconductance, a drain current and a gate-source voltage corresponding to FIG. 1 and FIG. 2. Refer to FIG. 2, FIG. 3, and FIG. 4. As illustrated in FIG. 2, a high electron mobility transistor 1 includes a substrate 10, an AlN nucleation layer 11, an AlGaN transition layer 12, a GaN channel layer 13, an AlN spacer layer 14, a GaN insertion layer 16, and an InAlGaN barrier layer 15. FIG. 1 is different from FIG. 2 in that the GaN insertion layer 16 of FIG. 2 is located between the AlN spacer layer 14 and the InAlGaN barrier layer 15. In FIG. 3 and FIG. 4, a dashed line represents a curve corresponding to FIG. 1 and a solid line represents a curve corresponding to FIG. 2. In FIG. 3, a gate-source voltage has a range of 2-10 V, wherein the gate-source voltage has a variation of −1 V. In FIG. 4, a drain-source voltage is 5 V. From FIG. 3 and FIG. 4, it is known that the drain current and the transconductance corresponding to FIG. 2 are respectively greater than the drain current and the transconductance corresponding to FIG. 1. This is because the GaN insertion layer 16 helps the InAlGaN barrier layer 15 to have a better atomic arrangement, thereby providing a better electron transporting capability. As a result, the high electron mobility transistor 1 with the GaN insertion layer 16 has a higher current density and a higher transconductance compared to a high electron mobility transistor 1 without the GaN insertion layer 16.

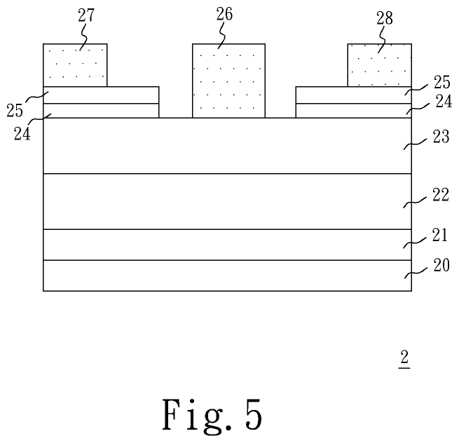

FIG. 5 is a cross-sectional view of a high electron mobility transistor according to an embodiment of the present invention. Referring to FIG. 5, a high electron mobility transistor 2 has the advantages of a GaN insertion layer. The high electron mobility transistor 2 includes a growth substrate 20, a lattice matching layer 21, a channel layer 22, an AlGaN layer 23, two GaN blocks 24, two InAlGaN blocks 25, a gate 26, a source 27 and a drain 28. The growth substrate 20 may include, but not limited to Si, GaN, SiC, or sapphire. The lattice matching layer 21 may include, but is not limited to GaN. The material of the channel layer 22 may change according to requirements. For example, the channel layer 22 is made of GaN. The lattice matching layer 21 is formed on the growth substrate 20. The channel layer 22 is formed on the lattice matching layer 21. The AlGaN layer 23 is formed on the channel layer 22. The AlGaN layer 23 includes a first area, a second area, and a third area. The second area is located between the first area and the third area. The AlGaN layer 23 is used as an active layer. Since the AlGaN layer 23 has a high energy bandgap, the high electron mobility transistor 2 has a low gate leakage. The two GaN blocks 24 are respectively formed on the first area and the third area of the AlGaN layer 23. The two InAlGaN blocks 25 are respectively formed on the two GaN blocks 24. The GaN block is equivalent to the GaN insertion layer. As a result, the high electron mobility transistor 2 has high current density, high transconductance, and high electron mobility to improve power output and have low-cost applications. The gate 26 directly interfaces the second area of the AlGaN layer 23. In other words, there is nothing between the second area of the AlGaN layer 23 and the gate 26. The source 27 and the drain 28 are respectively formed on the two InAlGaN blocks 25.

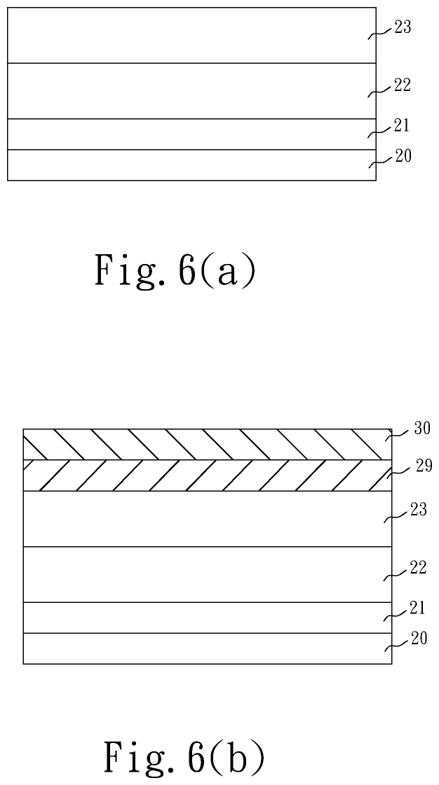

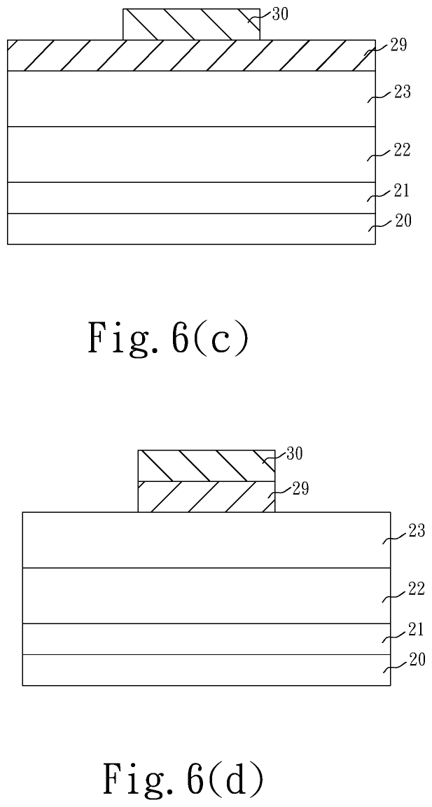

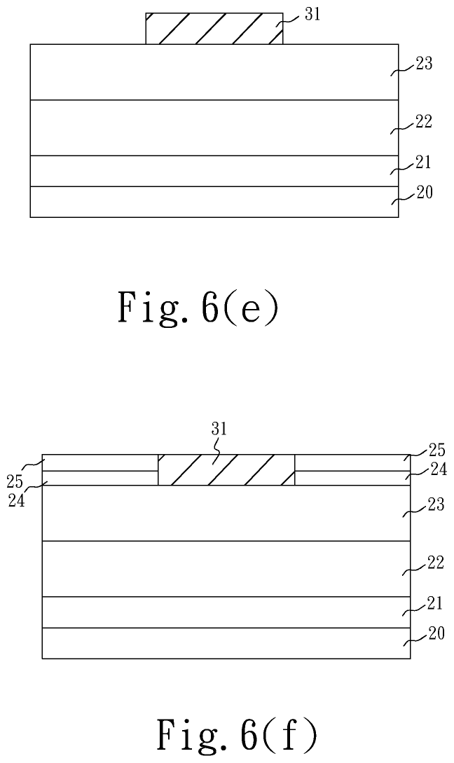

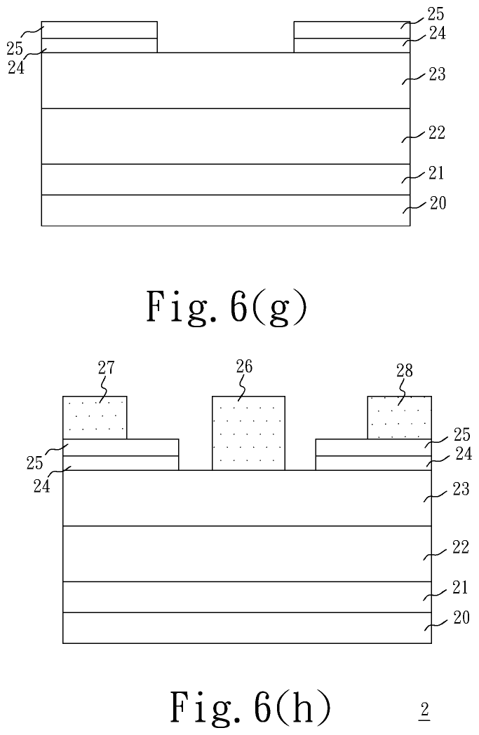

FIGS. 6(a)-6(h) are diagrams schematically illustrating the step of fabricating a high electron mobility transistor according to an embodiment of the present invention. The method for fabricating the high electron mobility transistor is described as follows. Refer to FIGS. 6(a)-6(h). As illustrated in FIG. 6(a), a lattice matching layer 21, a channel layer 22, and an AlGaN layer 23 is sequentially formed on a growth substrate 20. The AlGaN layer 23 includes a first area, a second area, and a third area. The second area is located between the first area and the third area. As illustrated in FIG. 6(b), an insulation layer 29 and a photoresist layer 30 are sequentially formed on the AlGaN layer 23. As illustrated in FIG. 6(c), the photoresist layer 30 directly above the first area and the third area of the AlGaN layer 23 is removed and the photoresist layer 30 directly above the second area of the AlGaN layer 23 is left. As illustrated in FIG. 6(d), the insulation layer 29 directly above the first area and the third area of the AlGaN layer 23 is removed and the insulation layer 29 directly above the second area of the AlGaN layer 23 is left. As illustrated in FIG. 6(e), the photoresist layer 30 directly above the second area of the AlGaN layer 23 is removed to form an insulation block 31 on the second area of the AlGaN layer 23. As illustrated in FIG. 6(f), two GaN blocks 24 are respectively formed on the first area and the third area of the AlGaN layer 23 and two InAlGaN blocks 25 are respectively formed on the two GaN blocks 24. The two GaN blocks 24 and the two InAlGaN blocks 25 are formed using metal-organic chemical vapor deposition (MOCVD), atomic layer deposition (ALD), or plasma enhanced chemical vapor deposition (PECVD), but the present invention is not limited thereto. As illustrated in FIG. 6(g), the insulation block 31 is removed. As illustrated in FIG. 6(h), a gate 26 is formed to directly interface the second area of the AlGaN layer 23 and a source 27 and a drain 28 are respectively formed on the two InAlGaN blocks 25. Provided that substantially the same result is achieved, the steps of the flowchart shown in FIGS. 6(a)-6(h) need not be in the exact order shown and need not be contiguous, that is, other steps can be intermediate. In some embodiments of the present invention, the steps of FIGS. 6(a)-6(d) may be omitted. After the step of FIG. 6(a), the step of FIG. 6(e) is directly performed to form the insulation block 31 on the second area of the AlGaN layer 23.

According to the embodiments provided above, the high electron mobility transistor and the method for fabricating the same form the GaN blocks between the AlGaN layer and the InAlGaN block to improve the electron mobility, current density, and transconductance.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A high electron mobility transistor comprising:
a growth substrate;
a lattice matching layer formed on the growth substrate;
a channel layer formed on the lattice matching layer;
an AlGaN layer formed on the channel layer, wherein the AlGaN layer comprises a first area, a second area, and a third area, and the second area is located between the first area and the third area;
two GaN blocks respectively formed on the first area and the third area of the AlGaN layer;
two InAlGaN blocks respectively formed on the two GaN blocks;
a gate directly interfacing the second area of the AlGaN layer; and
a source and a drain respectively formed on the two InAlGaN blocks.

2. The high electron mobility transistor according to claim 1, wherein the growth substrate comprises Si, GaN, SiC, or sapphire.

3. The high electron mobility transistor according to claim 1, wherein the lattice matching layer comprises GaN.

4. The high electron mobility transistor according to claim 1, wherein the channel layer comprises GaN.

5. A method for fabricating a high electron mobility transistor comprising:
sequentially forming a lattice matching layer, a channel layer, and an AlGaN layer on a growth substrate, wherein the AlGaN layer comprises a first area, a second area, and a third area, and the second area is located between the first area and the third area;
forming an insulation block on the second area of the AlGaN layer;
respectively forming two GaN blocks on the first area and the third area of the AlGaN layer;
respectively forming two InAlGaN blocks on the two GaN blocks;
removing the insulation block; and
forming a gate to directly interface the second area of the AlGaN layer and respectively forming a source and a drain on the two InAlGaN blocks.

6. The method for fabricating a high electron mobility transistor according to claim 5, wherein the step of forming the insulation block on the second area of the AlGaN layer comprises:
sequentially forming an insulation layer and a photoresist layer on the AlGaN layer;
removing the photoresist layer directly above the first area and the third area of the AlGaN layer and leaving the photoresist layer directly above the second area of the AlGaN layer;
removing the insulation layer directly above the first area and the third area of the AlGaN layer and leaving the insulation layer directly above the second area of the AlGaN layer; and
removing the photoresist layer directly above the second area of the AlGaN layer to form the insulation block on the second area of the AlGaN layer.

7. The method for fabricating a high electron mobility transistor according to claim 5, wherein the two GaN blocks and the two InAlGaN blocks are formed using metal-organic chemical vapor deposition (MOCVD), atomic layer deposition (ALD), or plasma enhanced chemical vapor deposition (PECVD).

8. The method for fabricating a high electron mobility transistor according to claim 5, wherein the growth substrate comprises Si, GaN, SiC, or sapphire.

9. The method for fabricating a high electron mobility transistor according to claim 5, wherein the lattice matching layer comprises GaN.

10. The method for fabricating a high electron mobility transistor according to claim 5, wherein the channel layer comprises GaN.
